(19) United States
(12) Patent Application Publication
(10) Pub. No.: US 2007/0216453 A1
(43) Pub. Date: Sep. 20, 2007

(54) Power-on reset signal generation circuit and method

(76) Inventors: Hemant Vispute, Bangalore (IN); Susmita Karmakar, Bangalore (IN); Badrinarayanan Kothandaraman, Bangalore (IN)

Correspondence Address: HAVERSTOCK & OWENS, LLP, 162 North Wolfe Road, Sunnyvale, CA, 94086, US

(21) Appl. No.: 11/725,031

(22) Filed: Mar. 16, 2007

Related U.S. Application Data
(60) Provisional application No. 60/798,064, filed on May 4, 2006.

(30) Foreign Application Priority Data
Mar. 16, 2006 (IN) 475/CHE/2006

(51) Int. Cl. H03L 7/00

(52) U.S. Cl. 327/143

(57) ABSTRACT

A power-on reset (POR) circuit (200) can include a voltage divider section (202) having a first divider resistor (R21), a second divider resistor (R22), and a diode connected transistor (N22). Signal generator section (204) can include a transistor N21 that is activated according to a potential generated by voltage divider section (202). A trip point of a POR circuit (200) can be based on a difference between the threshold voltages of transistors N21 and N22, and thus less susceptible to variations in threshold voltage.

This application claims the benefit of U.S. Provisional Patent Application Ser. No. 60/798,064 filed on May 4, 2006, the contents of which are incorporated by reference herein.

### TECHNICAL FIELD

The present invention relates generally to power-on reset circuits that generate a power-on reset signal for an integrated circuit device, and more particularly to a power-on reset circuit that activates a signal when a power supply voltage reaches a predetermined trip point.

### BACKGROUND OF THE INVENTION

Integrated circuit devices typically have a start-up procedure for establishing various functions when power is first provided to the integrated circuit (power-on), or in the event a power supply is interrupted (e.g., reset condition). In such arrangements, a power-on reset circuit can generate a transition in a power-on reset (POR) signal once a power supply has reached some predetermined level. Based on such a signal, other circuits can begin to operate in a normal fashion.

To better understand various features of the disclosed embodiments, a conventional POR circuit will first be described.

FIG. 3 shows a conventional POR circuit 300 that can include a voltage divider formed by resistors R1 and R2 arranged in series with one another between a high power supply voltage (Vcc) and a low power supply voltage (Vgnd). Resistors R1 and R2 can be connected to one another at a node 302. A transistor N31 can have a gate connected to node 302, a source connected to a low power supply voltage (Vgnd) and a drain connected to a high power supply (Vcc) via a resistor R3. A POR signal can be generated at the drain of transistor N31 (signal node 304). The POR signal can transition from high to low in a power-on and/or reset event.

The conventional POR circuit 300 operates by generating a potential at node 302 in the power-on/reset condition. In particular, when the potential at node 302 exceeds a threshold voltage (Vtn) of transistor N31, a low impedance path can be created between signal node 304 and low power supply voltage (Vgnd).

Thus, conventional circuit 300 can have a power supply trip point (Vtrip) for the POR signal given as follows:

Vtrip=Vtn*(R1+R2)/R2

where R1 and R2 are the resistance of resistors R1 and R2, respectively. From the above relationship, it is understood that

VtripαVtn (Vtrip is proportional to Vtn).

In addition, in the event R1=R2, then the following is true:

Vtrip=2*Vtn.

While the above-described conventional POR circuit 300 can generate a POR signal, such an approach may have some drawbacks.

A drawback to an approach like that of FIG. 3 can be dependence upon a threshold voltage Vtn in establishing a trip point. In particular, a threshold voltage may vary according to manufacturing process, operating temperature and/or operating voltage (PVT). As a result, if a POR trip point varies beyond an operating margin of other circuits of the integrated circuit device (e.g., latches, logic), a false power-on/reset condition may happen causing chip to operate in reset/shutdown condition.

As a result, if a manufacturing process has a relatively large variation in Vtn, an undesirably large variation can occur in a trip point of the conventional POR circuit.

It would be desirable to arrive at a power-on reset circuit that is less dependent upon a threshold voltage value than the above conventional approach.

### BRIEF DESCRIPTION OF THE DRAWINGS

FIG. 1 is a block schematic diagram of a power-on reset (POR) circuit according to a first embodiment of the present invention.

FIG. 2 is a schematic diagram of a POR circuit according to a second embodiment of the present invention.

FIG. 3 is a schematic diagram of a conventional POR circuit.

### DETAILED DESCRIPTION

Various embodiments of the present invention will now be described in detail with reference to a number of drawings. The embodiments show circuits and methods for activating a reset signal in response to a voltage level at a power supply node.

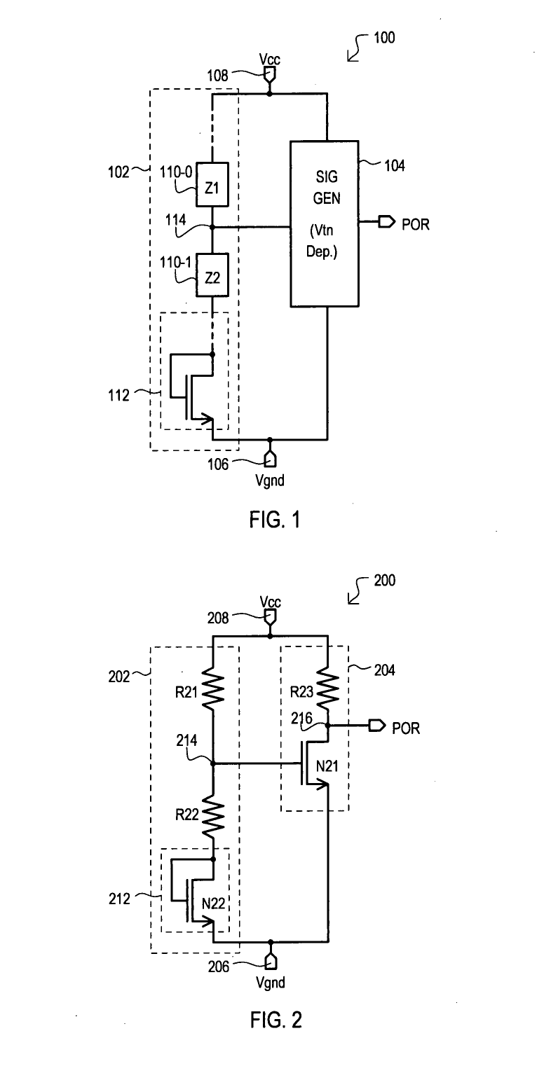

A power-on reset (POR) circuit according to a first embodiment is set forth in a block schematic diagram in FIG. 1 and designated by the general reference character 100. A POR circuit 100 can include a voltage divider section 102 and a signal generator section 104. A voltage divider section 102 can be connected between a first power supply node 106 and a second power supply node 108. A voltage divider section 102 can include two or more impedance elements (110-0 and 110-1) and a transistor section 112 arranged in series with one another. A trip node 114 can be formed at a connection between elements of the voltage divider section 102.

Impedance elements (110-0 and 110-1) can be passive impedance elements, preferably resistors. A transistor section 112 can include one or more transistors, preferably an n-channel insulated gate field effect transistor (IGFET) having its gate connected to its drain in a “diode” configuration.

In such an arrangement, a voltage generated at trip node 114 in a start-up (or reset) operation can vary according to a threshold voltage of a transistor 112.

A signal generator section 104 can activate a reset signal POR in response to the potential at node 114. In particular, a signal generator 104 can activate signal POR based on a comparison between the potential at trip node 114 and a threshold voltage (Vtn). That is, activation of signal POR is dependent upon a threshold voltage like that of section 112 in the voltage divider section 102.

In such an arrangement, variations in threshold voltage that affect a voltage dividing operation at node 114 can be similarly reflected in the activation point of signal generator section 104. As a result, a trip point can have less variation in response to fluctuations in threshold voltage due to variations in process, temperature and/or operating voltage (PVT).

A more detailed embodiment will now be described with reference to FIG. 2.

FIG. 2 is a schematic diagram of a POR circuit 200 according to a second embodiment of the present invention. A POR circuit 200 according to a second embodiment can include some of the same general sections as FIG. 1. Thus, like items are referred to by the same reference character but with the first digit being a “2” instead of a “1 ”.

In the embodiment of FIG. 2, a voltage divider section 202 can include a first divider resistor R21, a second divider resistor R22, and a diode connected transistor N22. A resistor R21 can be connected between a high power supply node 208 and a trip node 214. Resistor R22 can be connected between trip node 214 and drain/gate of transistor N22. Transistor N22 can have a gate and drain connected to resistor R22 and a source connected to a low power supply node 206.

Preferably, a transistor N22 can be an n-channel IGFET. Even more preferably, transistor N22 can be a low threshold voltage IGFET. As but one example, such a transistor can have threshold voltages less than those of other n-channel transistors within the circuit. Even more particularly, transistor N22 can have a lower threshold voltage than transistor N21 in section 204.

A signal generator section 204 can include a bias resistor R23 and a trip transistor N21. A bias resistor R23 can be connected between a high power supply node 208 and trip transistor N21. Trip transistor N21 can have a drain connected to resistor R23 at signal node 216, a gate connected to trip node 214, and a source connected to a low power supply node 206. A signal POR can be generated at a signal node 216.

A transistor N21 can be a standard (i.e., not low threshold voltage) n-channel IGFET. Accordingly, a transistor N21 can have a typical complementary metal-oxide-semiconductor (CMOS) threshold voltage. However, a transistor N21 has the same conductivity type (e.g., n-channel) as transistor N22 of voltage divider section 202.

In the arrangement of FIG. 2, a trip point for a power supply voltage (Vcc) can be given as follows:

Vtrip=(Vtn−Vtn_low)/X+Vtn_low

where X=R2/(R1+R2), Vtn is a threshold voltage of transistor N21, and Vtn_low is a threshold voltage of transistor N22.

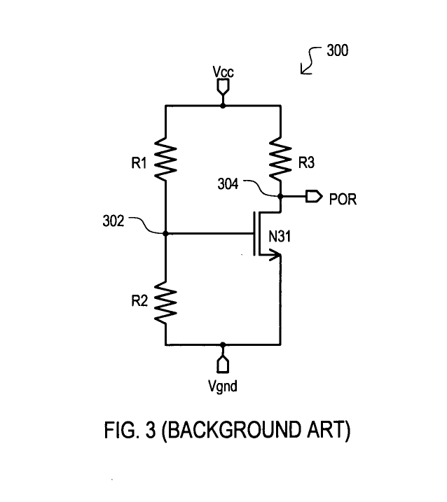

It is noted that the term “(Vtn−Vtn_low)/X” represents a difference between threshold voltages. As a result, differences in threshold voltage arising from PVT variations will cancel out, thus providing a more stable trip point (with respect to Vtn variation) than an conventional approach like that of FIG. 3.

In this way, a POR circuit can adapt to changes in threshold voltage resulting from PVT, rather than strictly varying according to such changes.

In addition, the inclusion of a diode connected transistor (e.g., N22, 112) can be accomplished with little additional circuit area. Thus, the present invention may be easily implemented into existing POR circuits.

Further, including such a diode connected transistor can allow resistors in the voltage divider to be reduced in size (lower resistance) while still drawing the same amount of current. This can free up additional area in an integrated circuit.

It is also noted that a diode connected transistor (e.g., N22, 112) can serve as current bias source for other sections of an integrated circuit. This can also free up additional area in an integrated circuit by eliminating some other current bias source.

The above embodiments can also advantageously enable a larger POR pulse width without increasing transistor size. In a conventional approach, utilizing only resistors, a POR signal pulse width may only be increased by increasing a resistance value. The above embodiments can utilize a diode connected transistor to adjust pulse width. For example, such a transistor width/length size can be varied, to thereby vary the amount of current drawn by a voltage divider leg.

Still further, the embodiments can be utilized across manufacturing technologies as no specialized circuit components need to be employed.

It is understood that the embodiments of the invention may be practiced in the absence of an element and or step not specifically disclosed. That is, an inventive feature of the invention can be elimination of an element.

Accordingly, while the various aspects of the particular embodiments set forth herein have been described in detail, the present invention could be subject to various changes, substitutions, and alterations without departing from the spirit and scope of the invention.

What is claimed is:

1. A circuit, comprising:
a first transistor with a first threshold voltage having a gate coupled to a trip node and a source-drain path coupled between a first power supply node and a reset node that provides a reset signal;
a first trip impedance device coupled to the trip node; and
a second transistor with a second threshold voltage less than the first threshold voltage having a source-drain path coupled between the first impedance device and the first power supply node.

2. The circuit of claim 1, wherein:
the first transistor and second transistor are insulated gate field effect transistors of a first conductivity type.

3. The circuit of claim 2, wherein:
the first conductivity type is n-channel.

4. The circuit of claim 1, wherein:
the first trip impedance device comprises a resistor.

5. The circuit of claim 1, wherein:
the second transistor has a gate coupled to its drain.

6. The circuit of claim 1, further including:
a second trip impedance device coupled between the trip node and a second power supply node.

7. The circuit of claim 6, wherein:
the second trip impedance device comprises a resistor.

8. The circuit of claim 6, wherein:
the second trip impedance device has a resistance that matches the first trip impedance device.

9. The circuit of claim 1, further including:
a bias impedance device coupled between the reset node and a second power supply node.

10. The circuit of claim 9, wherein:
the bias impedance device comprises a resistor.

11. The circuit of claim 1, wherein:
the second threshold voltage has an absolute value less than an absolute value of the first threshold voltage.

12. A method of generating a reset signal, comprising the steps of:
providing a resistance voltage divider circuit coupled to a power supply node to generate a trip potential at a trip node;
activating an insulated gate field effect transistor (IGFET) in response to the trip potential; and
introducing an IGFET threshold voltage drop into the voltage divider circuit.

13. The method of claim 12, wherein:
providing the resistance voltage divider circuit includes connecting at least two resistances in series at the trip node.

14. The method of claim 13, wherein:
the at least resistances having essentially the same resistance.

15. The method of claim 12, wherein:
activating the insulated gate field effect transistor in response to the trip potential includes coupling a gate of a trip transistor to the trip node.

16. The method of claim 12, wherein:
introducing the IGFET threshold voltage drop into the voltage divider circuit includes connecting a transistor in a diode configuration in series with resistors of the voltage divider circuit.

17. The method of claim 12, wherein:
introducing an IGFET threshold voltage drop into the voltage divider circuit includes introducing a threshold voltage drop less than that of the activated IGFET.

18. A power-on reset signal generating circuit, comprising:
a threshold adjusted voltage divider circuit coupled between a first power supply node and second power supply node that includes at least two resistors and at least one diode connected transistor arranged in series with one another; and
a reset signal generator comprising at least one transistor having a gate coupled to the threshold adjusted voltage divider circuit that generates a reset signal at its drain.

19. The power-on reset signal generating circuit of claim 18, wherein:
the threshold adjust voltage divider circuit includes
a diode connected first transistor having a source coupled to the first power supply node,
a first divider resistor coupled between the drain of the first transistor and a trip node, and
a second divider resistor coupled between the trip node and the second power supply node.

20. The method of claim 19, wherein:
a reset signal generator includes
a reset transistor having a source coupled to the first power supply node and a gate coupled to the trip node, the reset transistor having a larger magnitude threshold voltage than a threshold voltage of the first transistor, and
a bias impedance coupled between the drain of the reset transistor and the second power supply node.
